(19) United States
(12) Patent Application Publication
(10) Pub. No.: US 2025/0234674 A1
(43) Pub. Date: Jul. 17, 2025

(54) MASKING POSITIONED BETWEEN SOLAR CELLS

(71) Applicant: Maxeon Solar Pte. Ltd., Singapore (SG)

(72) Inventors: Jiang Li, Milpitas, CA (US); Hoi Hong Ng, San Jose, CA (US); Richard Sewell, Los Altos, CA (US); Paul Loscutoff, Castro Valley, CA (US)

(73) Assignee: Maxeon Solar Pte. Ltd., Singapore (SG)

(21) Appl. No.: 18/412,555

(22) Filed: Jan. 14, 2024

(51) Int. Cl. H01L 31/0216; H01L 31/0475

(52) U.S. Cl. CPC H10F 77/334; H10F 19/20; H10F 77/311

(57) ABSTRACT

Composite making regions are provided. These masking regions can include layers or other areas of different transparency where a first layer has a first transparency and a second layer has a different transparency. Masking regions can be positioned between adjacent photovoltaic cells of photovoltaic arrays.

### BACKGROUND

Photovoltaic (PV) cells, commonly known as solar cells, are devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit. When PV cells are combined in an array such as a PV module, the electrical energy collected from all of the PV cells can be combined in series or parallel arrangements, to provide power with a certain voltage and current. These arrangements may include interconnections between solar cells to electrically connect the solar cells.

### BRIEF DESCRIPTION OF THE DRAWINGS

FIG. 1A illustrates a top view of a two-dimensional array of PV cells with masked electrical interconnections as may be employed according to some embodiments.

FIG. 1B illustrates a first side view of the two- dimensional array of PV cells with masked electrical interconnections of FIG. 1A as may be employed according to some embodiments.

FIG. 1C illustrates a second side view of the two-dimensional array of PV cells with masked electrical interconnections of FIG. 1A as may be employed according to some embodiments.

FIG. 2A illustrates a top view of adjacent PV cells with masked electrical interconnections as may be employed according to some embodiments.

FIG. 2B illustrates a first side view of the adjacent PV cells with masked electrical interconnections of FIG. 2A as may be employed according to some embodiments.

FIG. 2C illustrates a second side view of the adjacent PV cells with masked electrical interconnections of FIG. 2A as may be employed according to some embodiments.

FIG. 3 illustrates cross-sectional views of three sets of multiple layers of materials as may be employed when masking electrical interconnects of PV cells according to some embodiments.

FIG. 4 illustrates cross-sectional views of the three sets of multiple layers of materials from FIG. 3 as may be employed in PV cells when masking electrical interconnects of the PV cells according to some embodiments.

FIG. 5 illustrates a process of applying an opaque masking layer within an interstitial space between PV cells and covering an electrical interconnection visible in that interstitial space, according to some embodiments.

FIG. 6 illustrates a top view of adjacent PV cells with masked electrical interconnections and pseudo-corners as may be employed according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components can be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112(f) for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead, the term “first” is used to differentiate this solar cell from another solar cell (e.g., a “second” solar cell).

“Based On.” As used herein, this term is used to describe one or more factors that affect a determination. This term does not foreclose additional factors that can affect a determination. That is, a determination can be solely based on those factors or based, at least in part, on those factors. Consider the phrase “determine A based on B.” While B can be a factor that affects the determination of A, such a phrase does not foreclose the determination of A from also being based on C. In other instances, A can be determined based solely on B.

“Coupled”—The following description refers to elements or nodes or features being “coupled” together. As used herein, unless expressly stated otherwise, means that “coupled” t one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it can completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

“Intervening layer” or “insulating layer” describes a layer that provides for electrical insulation, passivation, and/or inhibits light reflectivity. An intervening layer can be several layers, for example a stack of intervening layers. In some contexts, the intervening layer can be interchanged with a tunneling dielectric layer, while in others the intervening layer is a masking layer or an “antireflective coating layer” (ARC layer). Exemplary materials include silicon nitride, silicon oxynitride, silicon oxide (SiOx), silicon dioxide, aluminum oxide, amorphous silicon, polycrystalline silicon, molybdenum oxide, tungsten oxide, indium tin oxide, tin oxide, vanadium oxide, titanium oxide, silicon carbide and other materials and combinations thereof. In an example, the intervening layer can include a material that can act as a moisture barrier. Also, for example, the insulating material can be a passivation layer for a solar cell. In an example the intervening layer can be a dielectric double layer, such as a silicon oxide (SiOₓ), for example with high hydrogen content, aluminum oxide (Al₂O₃) dielectric double layer.

“About” or “approximately”. As used herein, the terms “about” or “approximately” in reference to a recited numeric value, including for example, whole numbers, fractions, and/or percentages, generally indicates that the recited numeric value encompasses a range of numerical values (e.g., +/−5% to 10% of the recited value) that one of ordinary skill in the art would consider equivalent to the recited value (e.g., performing substantially the same function, acting in substantially the same way, and/or having substantially the same result).

“Opaque”. As used herein, the term “opaque” refers to a property of light transmissibility. Different degrees of opacity are possible. 100% opacity, i.e., 0% light transmissibility, is not required for a material used herein to be considered “opaque”; rather, increased opacity relative to nearby materials, such as underlying materials, is required. Materials may have varying degrees of opacity, retardation of the transmission of light, visible as well as invisible light bandwidths, ranging from approximately 50% opaque to 100% opaque, e.g.: 50%, 55%, 60%, 65%, 70%, 75%, 80%, 85%, 90%, 95%,99%, and 100%.

“Transparent”. As used herein, the term “transparent” refers to a property of light transmissibility. Different degrees of transparency are possible. 100% transparency, i.e., 100% light transmissibility, is not required for a material used herein to be considered “transparent”; rather, increased transparency relative to nearby materials, such as overlying materials, is required. Materials may have varying degrees of transparency, transmission of light, visible as well as invisible light bandwidths, ranging from approximately 50% transparent to 100% transparent, e.g.: 50%, 55%, 60%, 65%, 70%, 75%, 80%, 85%, 90%, 95%, 99%, and 100%.

In addition, certain terminology can also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology can include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure can be practiced without these specific details. In other instances, well-known techniques are not described in detail in order to not unnecessarily obscure embodiments of the present disclosure.

This specification describes exemplary composite masking regions, which can be placed in or over gaps between adjacent solar cells in order to mask those gaps, portions of gaps, as well as mask any electrical interconnects spanning those gaps. In embodiments, PV cells, i.e., solar cells, are regularly placed next to each other in a grid pattern, in a non-grid pattern, randomly, or otherwise, when assembling a PV panel. A gap can exist between adjacent cells when laid out this way. The cells may be connected to each other or to at least one other cell using electrical interconnects (e.g., electrical connections providing for an electrical pathway between electrically interconnected objects). These interconnects and the gaps may be visible on an assembled PV panel. The gaps may contain a masking material positioned in the gap to hide or protect, or both electrical interconnects connecting the adjacent PV cells. The masking material may be in direct contact with the electrical interconnects and may be positioned away from the electrical interconnects in various embodiments.

A photovoltaic laminate may house PV cells, PV cell strings, and PV cell arrays in embodiments. In other words, a laminate of transparent, and/or opaque materials may be positioned above and/or below the PV solar cells in embodiments. This laminate material may serve to protect the solar cells from environmental hazards while also allowing for sunlight to reach the solar cells. The laminate material may include glass, clear polymers, and/or other materials.

Embodiments can include layered masking regions with the layers having different light transmitting properties. These light transmitting properties can differ from one face of the masking layer or other region to an opposite face of the masking layer or other region. These layered masking regions can be striated with layers or other regions of different transparency and/or opacity and these layers or other regions can have discrete borders or, in some embodiments, may not have discrete borders. These regions, which can be layers, can also have different widths as well as different sizes and shapes. In some embodiments, an outermost layer or other region can have a narrower width than a different layer or other region of the layered masking region. In some layered masking regions, an outermost layer can be wider than a different layer or other region. The layers or other regions can be detachable from each other and discrete as well as integrated or inseparable from other layers or other regions having different properties or made from different materials. As used herein, in an embodiment, the layered masking regions can be referred to as regions, masking layers, and/or layers.

Embodiments can be positioned in gaps between adjacent PV cells, above these gaps or otherwise near electrical interconnects between solar cells. In embodiments, a layer, or a portion of a layer, can include a transparent material that serves to affix to the cell while also limiting the amount of cell shading attributable to the transparent material. In other words, the transparent layer may serve to affix but may provide little if any masking or hiding. In embodiments, a masking region or a layered masking region, which may be used interchangeably, can include various types of materials. In an example, a layer can include a laminated film and/or a light redirecting material. A light redirecting material may be a material that reflects or redirects or partially reflects or redirects light striking the material. In embodiments, a layer or other region portion can comprise any shape or configuration. In an example, a first layer or other region can comprise a square, circular, oblong, rectangular, triangular, trapezoidal, hyperboloid, polygonal, and/or any other type of shape. In embodiments, a layer or other region portion can be positioned so as to be located at least partially or completely in a gap or other spacings between adjacent solar cells. In embodiments, the first layer can be the shape and size same as, follow, or conform to the shape of the gap or space between adjacent solar cells. In embodiments, a layer or other region portion can be located over an interconnect and in a gap between solar cells. In embodiments, a layer or other region portion can partially cover the interconnect. In embodiments, the first layer can be the same shape and size as, follow or conform to the shape of the interconnect.

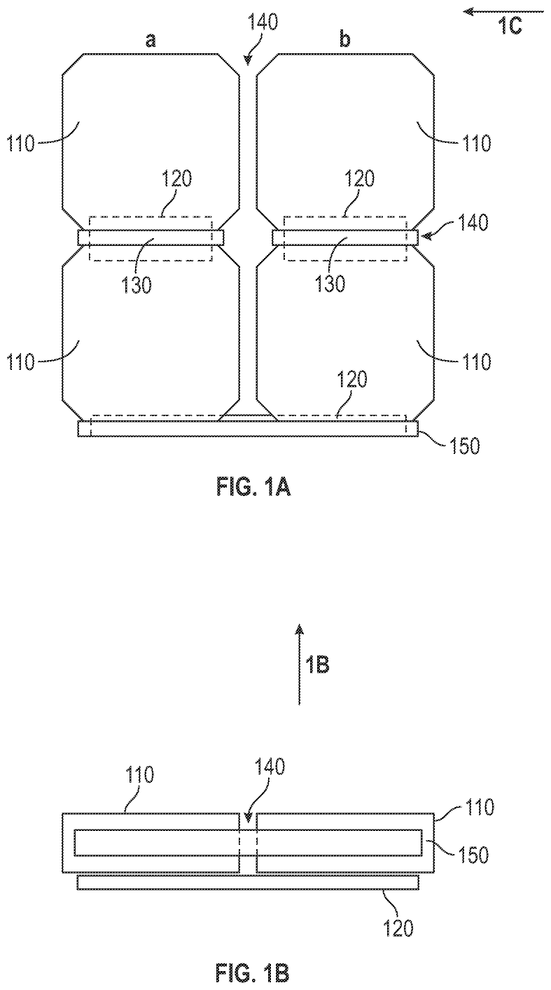

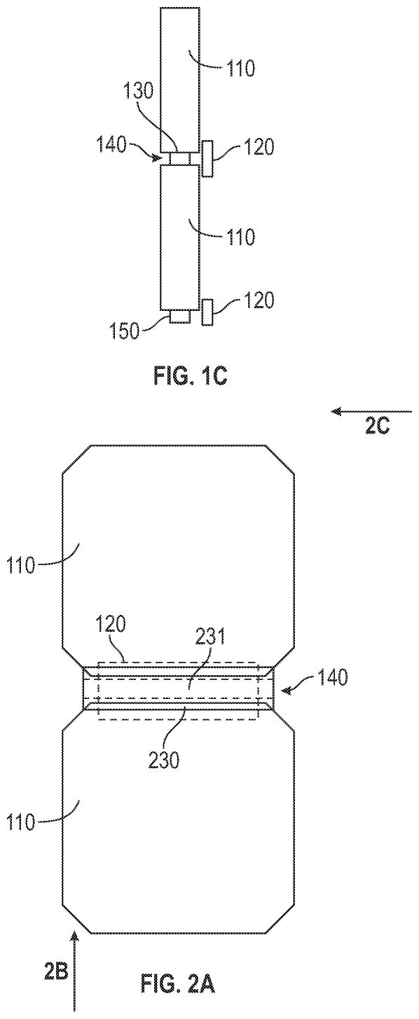

In embodiments, another, e.g., second, layer can also be employed where this layer can include an opaque material that can serve to cloak or mask, which may be used interchangeably, the interconnects between solar cells. One or more second layers may be employed. These second layers or other region portions can include a coating, a laminated film, light redirecting film, and/or other materials. This second layer or other region portion can be positioned in a gap so as to cover or visually obstruct the gap or other spacings between adjacent solar cells. In an embodiment, the second or other regions can visually obstruct an electrical interconnect between solar cells. In embodiments, the second layer can include any shape or configuration. In an example, the second layer can comprise a square, circular, oblong, rectangular, triangular, trapezoidal, hyperboloid, polygonal, and/or any other type of shape. These shapes may mimic the shape of the gap or spacing being filled. In some instances, the layer may bridge between adjacent PV cells, such a bridging configuration is shown in FIG. 1A.

In embodiments, transparent layers may be made of Polyethylene Terephthalate (PET) or other transparent plastic that is considered UV stable. In embodiments, opaque masking layers may comprise various materials and may be applied to various materials. In other words, the opaque layers may comprise opaque materials or may be made opaque through the addition of additional materials through painting or printing or other process. These additional processes and/or materials may comprise: acrylic ink, epoxy ink, polyurethane ink colored by various pigments. Laminated film, such as pigmented plastic like PET, may also be employed.

In embodiments, various lamination methods can be employed to assemble masking regions. These methods can include using multiple pieces of material, elongated continuous pieces of material such as tape, or other layering material, each having the same or differing transparent properties, and laminating two or more of the layers together. These layers can be uniformly laminated together and can be nonuniformly laminated together. For example, an upper, narrower layer can be laminated along the centerline of a lower layer as well as positioned off-center from the lower layer. The position of the layers can depend on the anticipated gaps between solar cells that are to be filled. These methods can also include applying the layers in gaps one at a time during assembly of a solar laminate with multiple solar cells. In other words, a base layer having a first transparency can be applied in a gap between two solar cells and a second layer, having less transparency can then be applied over this first layer in the gap or over the gap. Additional layers having similar or different properties may be applied in the gap or over the gap.

In embodiments, masking regions can be placed using ink-jet printing technologies, roller technologies, and other inking technologies as well. For example, a base substrate can be placed in a gap of adjacent solar cells and the transparency of this substrate layer can be reduced to approximately zero, over a portion of the width of the layer, by placing ink over a central portion of the substrate layer. In so doing, the outer edges of the substrate layer can be transparent but the central portion of the substrate can be opaque and positioned so as to prevent seeing some or all electrical interconnects between solar cells from a front surface of a solar panel containing the solar cells. In some embodiments, the masking regions can also be placed using screen printing, spin coating, and/or any other type of printing or deposition process can be used.

In embodiments, printing may also be undertaken after a transparent layer placement over an interconnect in a PV cell gap. In this way, an opaque layer (e.g., ink) width can be adjusted in some embodiments based on various gap sizing between two cells due to different gap design. Also, printing after a transparent layer placement may be accommodating to variations in gap sizing resulting from manufacturing variation.

The interconnects of embodiments can include any type of electrical conductor or material. In some examples, the interconnects can include an aluminum cut out, metal foil., aluminum foil, wires, aluminum wires and/or any other type of interconnect structure. In an example, the interconnects can include an anodized aluminum spanning the cells. The viability of these interconnects can be checked prior to and after the placement of the composite masking layers or other masking regions.

Light, heat, pressure-sensitive adhesive, and/or other bonding accelerants can be employed to bind a masking region in a solar cell gap as well as to bind layers or other regions of a mask to each other. The layers can be uniform in thickness and can have different thicknesses in a layer as well as when comparing layers. These thicknesses can be approximately 30 microns well as more and less thick. E.g., approximately 1μm, 3μm, 5 μm, 10 μm, 15 μm, 35 μm, 45 μm, etc. For example, transparent film thicknesses may range from approximately 25-125 microns and opaque layers may range from approximately 15-100 microns for printed or painted layers or regions and approximately 25-125 microns for laminated layers or regions.

Masking regions may comprise tape or other masking materials with pressure sensitive adhesives to adhere the masking material to or above the interconnect to be masked. The tape may be made from various materials including PET (Polyethylene Terephthalate), ETFE (a copolymer of ethylene and tetrafluoroethylene) and other polymer or non-polymer materials. Resiliency and toughness are properties that the materials comprising the tape or other mask may comprise.

As noted above, ink may be employed as a masking material. Some masking materials, including ink, may employ high reflectivity, may be UV stable, and may have characteristics that serve to slow or prevent yellowing of the substrate. This ink may be placed after the interconnection has been covered with a layer of material serving as a portion of the masking material or other purpose. This ink may be placed on tape or other masking material before the masking material is placed over the interconnect to be shielded. Thus, a tape with different transparencies may be employed in embodiments as a masking region. An edge or center portion of the tape may be opaque and this opaque portion may then be placed over the interconnects to be hidden. In some embodiments, two or more layers of tape may be used. A first layer of transparent material to completely cover the interconnection and a second opaque layer to mask a portion of the interconnection being masked from being visible from a side of the PV module.

Some embodiments may have “series” interconnections along strings of PV cells but not necessarily between these same strings of PV cells. These “series” interconnections, of a one-dimensional PV cell string, may be masked as taught herein. In some embodiments, however, strings of PV cells may be interconnected as well, forming a two-dimensional array of PV cells (connected in both series and parallel), and these interconnections may be masked as well. In embodiments, some but not all PV cell interconnections of a PV module may be masked, while in some embodiments, all PV cell interconnections of a PV module may be masked.

Embodiments may be employed with various electrical interconnection and stringing methods of PV cells. Shield tapes or other masking layers may be applied from the sun-side of the PV cells. These masking layers may be applied once the electrical interconnections between PV cells are in place. Thus, masking regions of embodiments may employ masking layers and/or other materials being applied from the electronics/device side of the PV cells in order to hide the metal interconnectors.

Masking regions of embodiments may employ various layers to provide masking. These layers may or may not be tapes and may themselves be opaque and transparent and variations therebetween. The layers may be of different widths. These layers may be applied to an array of PV cells from the sun receiving side (i.e., the device side). The layers may include a carrier film layer, a sticky layer (e.g., adhesive for more permanent or permanent adhesion), a less sticky layer (e.g., release adhesive for temporary adhesion), a masking or cloaking layer, and a transparent layer. The arrangement, juxtaposition, spacing, width, length, shape, thickness, and number of each layer may each be different in different embodiments.

Thus, in embodiments, a multilayer shield tape may be placed after an electrical interconnector is set so that the tape is being set from the device side of the PV cells. In other words, a multilayer shield tape may be placed from the device side of a PV cell array after the PV cells are electrically interconnected. Due to the shape of the wafers and distance between them, embodiments may employ masking layers that are less than 2 mm wide, although other widths, both larger and narrower, may be employed. A width of 2 mm or less may be beneficial in order to avoid overlapping adjacent cells and for placement between PV cells rather than on them. Embodiments may employ a masking layer to an electrical interconnector provided that the masking layer is nonconductive. The masking layers may employ materials that shield or otherwise protect electrical interconnectors.

Layers of the masking regions may be shaped to cover portions of a perimeter of a PV cell. For example, eight sided PV cells may have their missing rectangular corners covered by a transparent tape layer or other masking layer of embodiments. In such a configuration, the transparent tape layer or other layer may be dog bone shaped in order to cover the missing triangle corners (i.e., pseudo corners) of an eight sided PV cell.

Various layer materials of masking regions may be employed in embodiments. Exemplary layers may comprise carrier film layers, sticky layers, less sticky layers, opaque layers.

Carrier film layers may be employed to transport and protect an opaque or semi-transparent masking layer. The carrier films employed may comprise polyester (PET), polypropylene (PP), Polyvinyl chloride (PVC), paper, or other liners. In some embodiments, a carrier film may be peeled off from other masking layers after the masking layer stack is stuck to the wires. Thus, the carrier layer may not remain with a solar module after placement of the masking layer stack in some embodiments.

A less sticky or temporary sticky layer (i.e., release adhesive) may be employed in the masking layer stack. This layer may be used to help the carrier film by providing support and for affixing the opaque masking layer to a gap of PV cells or an electrical interconnect. The less sticky or temporary sticky layer (release adhesive) may employ a less sticky adhesive or may achieve temporary adhesion through temporary bonding solutions.

An opaque masking layer may be employed in embodiments. Such a layer may have the same color as the background of the solar module, normally white or black. An opaque layer may be made of either a rigid material, like polyester (PET), a soft material, like Polyolefin elastomer (POE, mixed with white TiO2 for white color) and Ethylene-vinyl acetate (EVA), or inks. Other materials as taught herein may also be employed. The size and shape (e.g., straight or dogbane shape) of the opaque masking layer may depend on the shape of the PV cell and/or the dimension of PV cell to PV cell spacing. In some embodiments, the length of the masking layer may be the same as the size of the cell, but the width may be a little bit narrower than the cell-cell gap. By increasing the width of the opaque layer, the portion of the electrical interconnector exposed to the sunny side of the module, and potentially visible to an observer, may be minimized.

A sticky layer may be employed to adhere an opaque masking layer to an electrical interconnector and avoid shifting in later manufacturing or handling processes. A sticky layer may comprise adhesives, like acrylate, silicone, rubber, vinyl, and so on. A sticky layer may comprise some thermoset polymer, like POE, EVA, LLDPE, and so on. When a thermoset is employed, the masking layer may be affixed to the interconnector through heat-tacking or other adhesion technique. The shape and dimension of a sticky layer may mimic the shape and dimension of an opaque layer as well as other layers.

Transparent layers may also be employed. These transparent layers may be wider than the masking layer. Transparent layers may be employed as the base of transparent tapes, like vinyl polyethylene (VPE), PET, PVC, and Ethylene Tetrafluoroethylene (ETFE). Transparent layers may be positioned to the sunny side of the cell so that transparent layers may be highly transparent and have good durability.

In some embodiments, the positioning of the masking region may also provide some protection to the electrical interconnector from corrosion. In other words, a masking region located in a gap or near a gap may provide some protection to nearby electrical interconnects by virtue of the location of the masking region and the electrical interconnects to each other. Embodiments may also be employed to mask other parts of a PV module, e.g., an exposed bus bar.

Embodiments may comprise a photovoltaic array comprising a plurality of photovoltaic cells, wherein at least some of the photovoltaic cells of the plurality may be electrically interconnected to each other across a gap between adjacent photovoltaic cells of the plurality. These photovoltaic arrays may also comprise a masking region positioned within the gap, the masking region may have a first width along an upper surface and a second width along a lower surface, the first width and the second width less than a width of the gap between adjacent photovoltaic cells. In some embodiments, the masking region may have a higher opacity in the first width than the second width. Some embodiments may further comprise an electrical interconnection located underneath the masking region. As to the masking region, the first width and the second width may be the same, and the lower surface may be completely opaque.

Embodiments may comprise a photovoltaic panel comprising a plurality of photovoltaic cells arranged in a two-dimensional array, wherein at least one of the photovoltaic cells of the plurality may be electrically interconnected to another photovoltaic cell of the plurality across a gap between these electrically interconnected photovoltaic cells, and may also comprise a masking region positioned within the gap, the masking region having a first width along a first surface of the masking region and a second width along a second surface of the masking region, the first width and the second width smaller than the gap. In some embodiments, the masking region may have a higher opacity in the first width than the second width and the first width and the second width may not be the same. In embodiments, the masking region may be 100% opaque. In some embodiments the masking region comprises one or more of PET (PolyEthylene Terephthalate, POE (PolyOlefinElastomer), and EVA (Ethylene-Vinyl Acetate). In some embodiments, the masking region comprises a carrier layer, a first sticky layer, a masking layer and a second sticky layer. In some embodiments the masking region comprises a masking layer and a transparent layer. In some embodiments a gap between PV cells is an end-to-end gap between two photovoltaic cells of a plurality of photovoltaic cells. In some embodiments, the masking region in the gap is visible.

Embodiments may comprise a photovoltaic array comprising a plurality of photovoltaic cells, wherein at least some of the photovoltaic cells of the plurality are electrically interconnected via a gap between adjacent photovoltaic cells, and may further comprise a making region is positioned within the gap, the masking region having a width along an opaque surface, the width smaller than a width of the gap, wherein the masking region may be positioned above an electrical interconnection in the gap. In certain embodiments the masking region may be in contact with the electrical interconnection. In some embodiments, the gap may have a varying width across its length. In some embodiments, the masking region comprises a tape and an ink. The photovoltaic may employ a masking region comprises a first tape and a second tape, the first tape adhesively connected to the second tape and the first tape may have a uniform thickness and the second tape may have a uniform thickness. In some embodiments, the first tape may have a uniform width and the second tape may have a uniform width. In some embodiments photovoltaic cells of the plurality of photovoltaic cells may be arranged adjacent one another in a two-dimensional grid pattern. In some embodiments, photovoltaic cells of a plurality of photovoltaic cells may be arranged adjacent one another in a one-dimensional linear array pattern.

FIG. 1A illustrates a top view of a two-dimensional array of PV cells with masked electrical interconnections as may be employed according to some embodiments. FIG. 1A shows the top side of four PV cells 110. These PV cells form two strings a and b with electrically interconnected PV cells and the bottom of these two strings are electrically interconnected also. Electrical interconnections are labelled 120. These electrical interconnections 120 may be the various traces, wires, etc. as taught herein. As can also be seen in FIG. 1A, the electrical interconnections extend from one PV cell to another and reside below the masking regions 130. The space between the adjacent cells is labelled 140. The masking regions 130 may be positioned between the PV cells and may occupy less than the entire width or length of the PV cells as is shown in FIG. 1A. The electrical interconnections may also be centered or not centered below the masking regions 130, as is also shown in FIG. 1A. The masking region 150 of FIGS. 1A-1C spans two PV cells. Thus, in some embodiments, a masking region may be present in the gap between PV cells as well as in other areas not necessarily in this gap. Here, the bottom of PV string is electrically connected in series with the bottom of PV string b and this electrical connection traverses a side-to-side gap between the PV cells of string a and string b. This side-to-side gap is covered by the masking region 120. Comparatively, the gap 140 may be thought of an end-to-end gap. In the end-to-end gap, the masking region need not extend across two strings of PV cells because the electrical connections do not in this instance.

FIG. 1B illustrates a side view of the two-dimensional array of PV cells with masked electrical interconnections of FIG. 1A as may be employed according to some embodiments. The masking region 150 in FIG. 1B is present near to but not in contact with the electrical interconnect 120. In some embodiments the masking region may be in contact with the electrical interconnect 120. The masking region 150 is also shown across the gap 140 between PV cells and in contact with edges of the PV cells. The electrical interconnect 120 is shown directly below and directly attached to the PV cells 110. Arrow 1B for FIG. 1A show the direction of view illustrated in FIG. 1B. The PV cells 110 are shown to have the same dimensions in FIGS. 1A-1C, however, PV cells of different shapes and sizes may also be employed in embodiments.

FIG. 1C illustrates a side view of the two-dimensional array of PV cells with masked electrical interconnections of FIG. 1A as may be employed according to some embodiments. Arrow 1C on FIG. 1A shows the direction of view illustrated in FIG. 1C. The masking region 130 of FIG. 1C is shown above and not in direct contact with the electrical interconnection 120. The electrical interconnect 120 is shown directly below and directly attached to the PV cells 110. As can be seen in both FIG. 1B and FIG. 1C the masking regions 130 and 150 fit within the gaps 140 between adjacent PV cells 110.

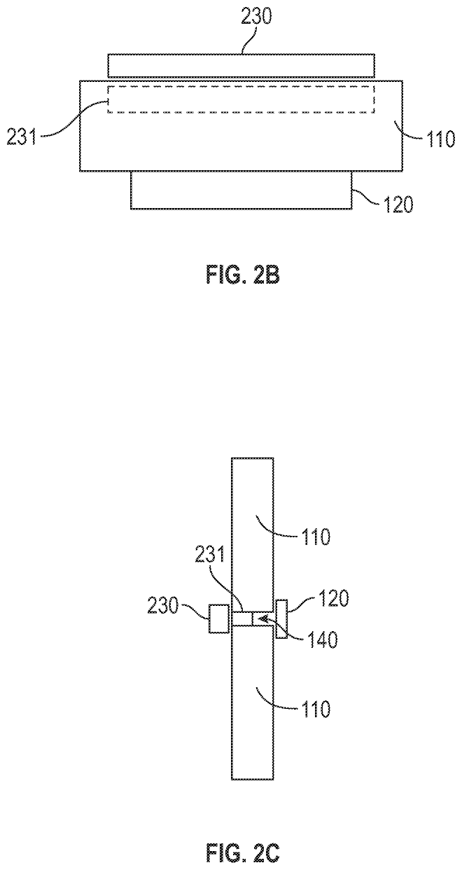

FIG. 2A illustrates a top view of adjacent PV cells with masked electrical interconnections as may be employed according to some embodiments. The PV cells 110 are shown electrically interconnected via electrical interconnect 120 and layers 230 and 231 are shown comprising the masking region. Layer 230 is shown sitting above the PV cells 110 while layer 231 is shown positioned between the PV cells. Layer 231 may be opaque while layer 230 may be transparent. The masking region, which comprises layers 230 and 231, is shown in FIG. 2A as overlapping the PV cells as well as fitting in between them.

FIG. 2B illustrates a side view of the adjacent PV cells with masked electrical interconnections of FIG. 2A as may be employed according to some embodiments. Arrow 2B show the direction of view illustrated in FIG. 2B. Layers 230 and 231 are shown comprising the masking region. Layer 230 is shown sitting above the PV cells 110 while layer 231 is shown positioned between the PV cells. Layer 231 may be opaque while layer 230 may be transparent. The gap between the PV cells 110 is labelled 140.

FIG. 2C illustrates a side view of the adjacent PV cells with masked electrical interconnections of FIG. 2A as may be employed according to some embodiments. Arrows C show the direction of view illustrated in FIG. 2C. Layers 230 and 231 are shown comprising the masking region. Layer 230 is shown sitting above the PV cells 110 while layer 231 is shown positioned between the PV cells. Layer 231 may be opaque while layer 230 may be transparent. Electrical interconnect 120 is shown below the PV cells 110 and is shown as a trace or wire—other connection topologies may also be employed.

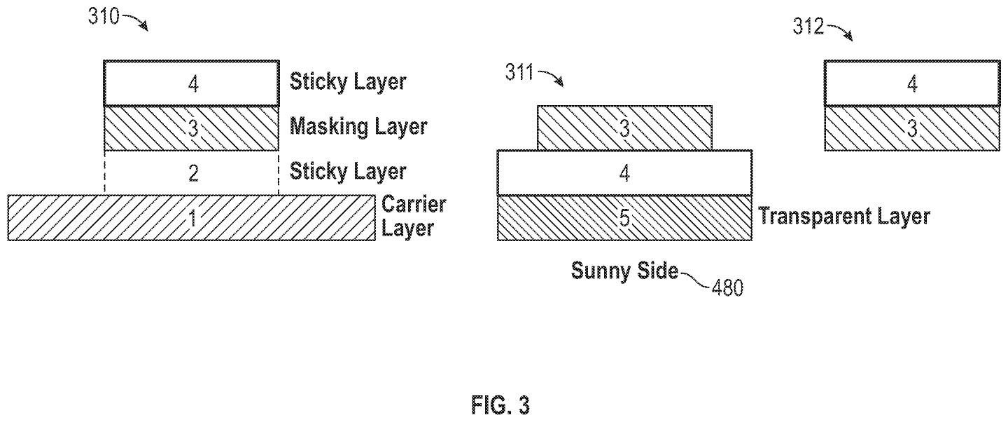

FIG. 3 illustrates side cross-sectional view of three masking regions with multiple layers of materials as may be employed when masking electrical interconnects of PV cells according to some embodiments. Each masking region is shown with multiple layers. Masking region 310 is shown with four layers while masking region 311 is shown with three layers and masking region 312 is shown with two layers. Layers labelled as 1 are shown as a carrier layer described herein, Layers labelled as 2 are a less sticky or temporarily sticky layer as described herein. Layers labelled as 3 are a masking layer as described herein. Layers labelled as 4 are a sticky layer as described herein. Layers labelled as 5 are a transparent layer as described herein. Embodiments may include one or more of these various layers in various orders and in various combinations and numbers. Other layers may also be employed. Layer 1, a carrier layer may be used to position other layers in a gap between PV cells and may be subsequently removed after the other layers are positioned.

Layer 1 in some embodiments may comprise one or more of the following examples and their cognates: PET, PP, PVC, and paper can be used as layer 1. Layer 2 in some embodiments may comprise one or more of the following examples and their cognates: polyimide, polyurethane, silicone, or acrylic adhesives with pattern design to limit the contact area with layer 3 or surface treatments to reduce the adhesion. Layer 3 in some embodiments may comprise one or more of the following examples and their cognates: PET, POE, and EVA. Heat-pressure lamination may also be employed when layer 3 is PET. Layer 4 in some embodiments may comprise one or more of the following examples and their cognates: silicone and acrylic base adhesives. Layer 5 may be applied to the sunny side of the cell, in some embodiments may comprise one or more of the following examples and their cognates: ETFE and VPE.

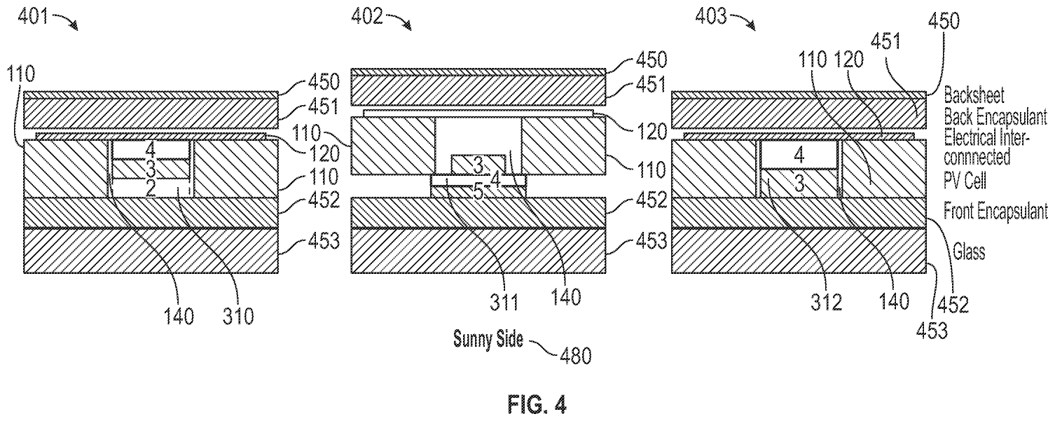

FIG. 4 illustrates side cross-sectional view of the three sets of masking regions with multiple layers of materials from FIG. 3 as may be employed in PV cells when masking electrical interconnects of the PV cells according to some embodiments. The backsheet 450, back encapsulant 451, electrical interconnector 120, PV cell 110, front encapsulant 452, and glass 453 are each labelled in FIG. 4. In some embodiments, the back encapsulant may be dark or black while the front encapsulant may be clear. Example 401 shows the masking region 310 of FIG. 3, with the carrier layer 1 removed after placing the masking region 310 in combination with two PV cells according to some embodiments. As can be seen at 401, the layers 2-4 are within the gap between PV cells 110 and above the electrical interconnect 120 because the sun-side 480 of the PV cells is shown at the bottom of FIG. 4. Thus, during application, the carrier layer 1 may be used for positioning the masking region and may be subsequently removed after positioning the masking region. As can be seen at 402, layers 4 and 5 (a sticky layer 4 and a transparent layer 5) may be wider than the gap between PV cells 110. This width may be used to support the masking layer 3 in the gap and position the masking layer 3 over and above the electrical interconnector 120. As can be seen at 403, the masking region 312 may be positioned in contact with the electrical interconnector 120 and may reside completely in the gap 140 between PV cells 110.

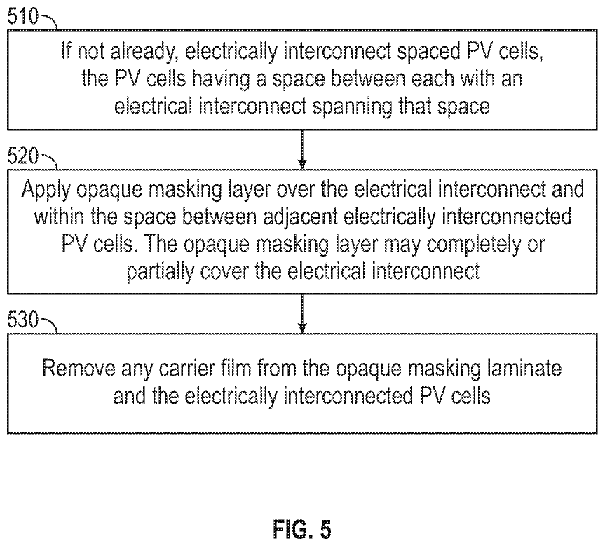

FIG. 5 illustrates a process of applying an opaque masking layer within an interstitial space between PV cells and covering an electrical interconnection visible in that interstitial space according to some embodiments. 510 of FIG. 5 explains that in embodiments, if not already completed, processes may comprise electrically interconnecting spaced PV cells with an electrical interconnect spanning a gap between PV cells. 520 of FIG. 5 explains that a masking region may be applied over the electrical interconnect and may be positioned partially or completely within a gap between adjacent PV cells. The masking region may comprise one or more opaque masking layers and may partially or completely cover the electrical interconnect. 530 of FIG. 5 explains that any carrier film present in the masking region may be removed after placement of the masking region. Other processes may also be employed in embodiments. These other processes may comprise adding or removing any of the features taught herein.

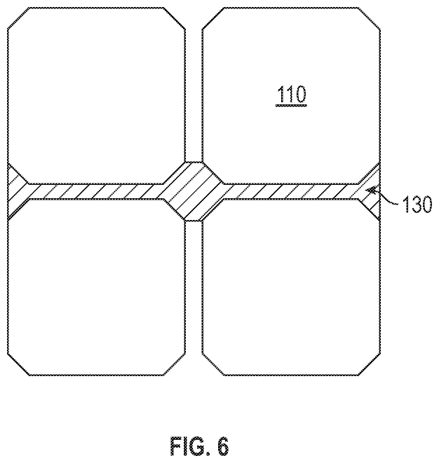

FIG. 6 illustrates a top view of adjacent PV cells with masked electrical interconnections and pseudo-corners as may be employed according to some embodiments. As can be seen in FIG. 6 the masking regions 130 may be present in the diamond like spaces between pseudo-corners 620 of adjacent PV cells 110. By placing masking regions in these enlarged spaces created by the truncated corners of adjacent PV cells, interconnections or other elements present in the enlarged spaces may be masked by the masking regions and may not be seen or may be less visible or only partially visible.

In embodiments, masking can also be referred to as covering, hiding, cloaking, or obstructing from view. In embodiments, the plurality of solar cells can include individual solar cells adjacent and/or near to one another. In embodiments, the plurality of solar cells can refer to a solar cell string as well as a matrix of solar cells. In embodiments, the layers can be uniform in thickness and/or can have different thicknesses. In an example, opaque material can serve to obstruct the view of interconnects 120 from a front side of a solar panel. In embodiments, layer thicknesses can be approximately 30 μm as well as more and less thick. E.g., approximately 1 μm, 3 μm, 5 μm, 10 μm, 15 μm, 35 μm, 45 μm, etc.

The electrical interconnectors can include any type of electrical conductor material. In some examples, the interconnections can include an aluminum cut out, metal foil (such as aluminum foil and/or copper foil), wires, aluminum wires, copper wires, and/or any other type of interconnect structure. In an example, the interconnectors can include an anodized aluminum spanning the cells. In embodiments, a masking region may be present between solar cells even though the particular solar cells are not interconnected with an interconnection. These shapes may vary and may include dog bone mask configurations as shown herein as well as rectangular, polygonal, square, circular, elliptical, oval, and other configurations suited to provide masking properties as described herein.

In embodiments, the multiple solar cells can be electrically connected by a plurality of electrical interconnections. In embodiments, the multiple solar cells electrically connected by a plurality of interconnections can be referred to as a solar cell matrix. In embodiments, the solar cell matrix can include a plurality of solar cell strings, as described above. In embodiments, the solar cell matrix can include a plurality of individual solar cells. In embodiments, the plurality of solar cells can be electrically connected by the plurality of interconnections. In embodiments, a single interconnect from the plurality of interconnections can be used to electrically connect one solar cell to another solar cell as shown. In embodiments, two or more interconnections of the plurality of interconnects can be used to electrically connect two solar cells. In embodiments, although four solar cells are shown electrically connected by the plurality of interconnects, instead two solar cells can be connected by a single interconnection. In an example, at least two solar cells can be connected in series or parallel electrical configuration. Although as shown, each solar cell is connected to at least two other solar cells, in embodiments, a solar cell can be connected to at least one other solar cell. In embodiments, the present layering and/or masking may be employed with any solar cell configuration having visible interconnections. In embodiments, the present layering and/or masking may be employed with any solar cell configuration having gaps, even if visible interconnections are not present.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure. The scope of the present disclosure includes any feature or combination of features disclosed herein (either explicitly or implicitly), or any generalization thereof, whether or not it mitigates any or all of the problems addressed herein. Accordingly, new claims can be formulated during prosecution of this application (or an application claiming priority thereto) to any such combination of features. In particular, with reference to the appended claims, features from dependent claims can be combined with those of the independent claims and features from respective independent claims can be combined in any appropriate manner and not merely in the specific combinations enumerated in the appended claims.

What is claimed is:

1. A photovoltaic array comprising:
a plurality of photovoltaic cells,
wherein at least some of the photovoltaic cells of the plurality are electrically interconnected to each other across a gap between adjacent photovoltaic cells of the plurality, and
a masking region positioned within the gap, the masking region having a first width along an upper surface and a second width along a lower surface, the first width and the second width less than a width of the gap between adjacent photovoltaic cells.

2. The photovoltaic array of claim 1 wherein the masking region has a higher opacity in the first width than the second width.

3. The photovoltaic array of claim 1 further comprising an electrical interconnection located underneath the masking region, the first width and the second width are the same, and the lower surface is completely opaque.

4. A photovoltaic panel comprising:
a plurality of photovoltaic cells arranged in a two-dimensional array,
wherein at least one of the photovoltaic cells of the plurality is electrically interconnected to another photovoltaic cell of the plurality across a gap between these electrically interconnected photovoltaic cells, and a masking region is positioned within the gap, the masking region having a first width along a first surface of the masking region and a second width along a second surface of the masking region, the first width and the second width smaller than the gap.

5. The photovoltaic panel of claim 4 wherein the masking region has a higher opacity in the first width than the second width and wherein the first width and the second width are not the same.

6. The photovoltaic panel of claim 4 wherein the masking region is 100% opaque.

7. The photovoltaic panel of claim 4 wherein the masking region comprises one or more of PET (PolyEthylene Terephthalate, POE (PolyOlefinElastomer), and EVA (Ethylene-Vinyl Acetate).

8. The photovoltaic panel of claim 4 wherein the masking region comprises a carrier layer, a first sticky layer, a masking layer and a second sticky layer.

9. The photovoltaic panel of claim 4 wherein the masking region comprises a masking layer and a transparent layer.

10. The photovoltaic panel of claim 4 wherein the gap is an end-to-end gap between two photovoltaic cells of the plurality of photovoltaic cells.

11. The photovoltaic panel of claim 4 wherein the masking region in the gap is visible.

12. A photovoltaic array comprising:
a plurality of photovoltaic cells,
wherein at least some of the photovoltaic cells of the plurality are electrically interconnected across a gap between adjacent photovoltaic cells, and
a masking region is positioned within the gap, the masking region having a width along an opaque surface, the width smaller than a width of the gap,
wherein the masking region is positioned above an electrical interconnection in the gap.

13. The photovoltaic array of claim 12 wherein the masking region is in contact with the electrical interconnection.

14. The photovoltaic array of claim 12 wherein the gap has a varying width across its length.

15. The photovoltaic array of claim 12 wherein the masking region comprises a tape and an ink.

16. The photovoltaic array of claim 12 wherein the masking region comprises a first tape and a second tape, the first tape adhesively connected to the second tape.

17. The photovoltaic array of claim 16 wherein the first tape has a uniform thickness and the second tape has a uniform thickness.

18. The photovoltaic array of claim 16 wherein the first tape has a uniform width and the second tape has a uniform width.

19. The photovoltaic array of claim 12 wherein photovoltaic cells of the plurality of photovoltaic cells are arranged adjacent one another in a two-dimensional grid pattern.

20. The photovoltaic array of claim 12 wherein photovoltaic cells of the plurality of photovoltaic cells are arranged adjacent one another in a one-dimensional linear array pattern.
